(19) United States
(12) Patent Application Publication
(10) Pub. No.: US 2011/0260203 A1
(43) Pub. Date: Oct. 27, 2011

(54) LIGHT EMITTING DIODE STRUCTURE AND FABRICATION METHOD THEREOF

(75) Inventors: Hsien-Chia Lin, Taipei (TW); Tzu-Yu Tang, Taipei (TW)

(73) Assignee: EVERLIGHT ELECTRONICS CO., LTD., NEW TAIPEI CITY (TW)

(21) Appl. No.: 13/090,264

(22) Filed: Apr. 20, 2011

(30) Foreign Application Priority Data
Apr. 23, 2010 (TW) 99112860

(51) Int. Cl. H01L 33/38

(52) U.S. Cl. 257/99; 438/22; 257/E33.065

(57) ABSTRACT

A light emitting diode structure including a light emitting device layer, a patterned dielectric layer, a first ohmic contact layer, a conductive layer, a first electrode layer and a second electrode layer is provided. The light emitting device layer has a first surface and a second surface opposite to the first surface. The patterned dielectric layer disposed on the first surface has a plurality of openings exposing a portion of the light emitting device layer. The first ohmic contact layer is disposed on the patterned dielectric layer and connected with the first light emitting device layer through the openings. The conductive layer is disposed on the first ohmic contact layer. The first electrode layer is disposed on the conductive layer, and the conductive layer is located between the first ohmic contact layer and the second electrode layer. A fabrication method of the light emitting diode structure is also provided.

### CROSS-REFERENCE TO RELATED APPLICATION

This application claims the priority benefit of Taiwan application serial no. 99112860, filed Apr. 23, 2010. The entirety of the above-mentioned patent application is hereby incorporated by reference herein and made a part of this specification.

### BACKGROUND OF THE INVENTION

1. Field of the Invention

The invention relates generally to light emitting diode, and more particularly to a light emitting diode structure.

2. Description of Related Art

Due to advantages of long lifetime, small volume, great resistance to vibration, low heat emission, and low power consumption, light emitting diodes (LEDs) have been extensively applied in various home appliances and indicators or light sources of various instruments.

Typically speaking, high brightness vertically oriented LEDs have an issue of irregular current distribution, as well as a highly directional property in a provided light, in which the high directional property refers to a highly concentrated light field distribution of the light. For example, the light field intensity is strongest while viewing the LED directly on top, whereas the light field intensity rapidly weakens as deviation from the directly positive direction occurs. This issue is even more prominent while employing a distributed Bragg reflector (DBR).

Moreover, conventional vertically oriented LEDs typically require two substrate transfer processes during fabrication. Therefore, the steps involved in fabricating the conventional vertically oriented LEDs are substantially more complex.

### SUMMARY OF THE INVENTION

An aspect of the invention provides a light emitting diode (LED) structure having a preferable optical performance and electrical characteristic.

Another aspect of the invention provides a method of fabricating an LED structure, in which the fabrication method can not only fabricate the aforesaid LED structure, the method also has substantially simpler steps.

An aspect of the invention provides an LED structure, including a light emitting device layer, a patterned dielectric layer, a first ohmic contact layer, a conductive layer, a first electrode layer, and a second electrode layer. The light emitting device layer has a first surface and a second surface. The patterned dielectric layer is disposed on the first surface, and the patterned dielectric layer has a plurality of openings to expose a portion of the light emitting device layer. The first ohmic contact layer is disposed on the patterned dielectric layer, and the first ohmic contact layer is connected with the light emitting device layer through the openings. The conductive layer is disposed on and connected with the first ohmic contact layer. The first electrode layer is disposed on the second surface and covers a portion of the light emitting device layer. The second electrode layer is disposed on the conductive layer, and the conductive layer is disposed between the first ohmic contact layer and the second electrode layer.

According to an embodiment of the invention, the first ohmic contact layer is conformal with the patterned dielectric layer.

According to an embodiment of the invention, the conductive layer is connected with the first ohmic contact layer through the openings.

According to an embodiment of the invention, the LED structure further includes a second ohmic contact layer covering the first ohmic contact layer and disposed between the first ohmic contact layer and the conductive layer. According to an embodiment of the invention, the second ohmic contact layer is adapted to fill the openings, and the second ohmic contact layer is a planar layer.

According to an embodiment of the invention, the first ohmic contact layer is adapted to fill the openings, and the first ohmic contact layer is a planar layer.

According to an embodiment of the invention, a material of the patterned dielectric layer comprises SiOₓ, SiNₓ, SiNₓO_{y}, SiₓC_{y}, HfO, AlOₓ, or photoresist materials, wherein x, y are larger than 0 and smaller than 4.

According to an embodiment of the invention, a material of the first ohmic contact layer comprises metallic materials, transparent conductive oxides, or semiconductor materials.

According to an embodiment of the invention, the first ohmic contact layer has a single layer structure or a multi-layer structure.

According to an embodiment of the invention, a pattern formed by the openings on the patterned dielectric layer includes a structure of a protruded or recessed symmetrical pattern, asymmetrical pattern, trapezoidal pattern, or conical pattern.

Another aspect of the invention provides a method of fabricating an LED structure, the method including at least the following steps. First, a substrate is provided. Next, a light emitting device layer is formed on the substrate, in which the light emitting device layer has a first surface and a second surface opposite to the first surface, and the second surface is in contact with the substrate. Thereafter, a dielectric layer is formed on the first surface of the light emitting device layer. Then, the dielectric layer is patterned to form a patterned dielectric layer having a plurality of openings, in which the openings expose a portion of the light emitting device layer. Next, a first ohmic contact layer is formed on the patterned dielectric layer, in which the first ohmic contact layer is connected with a portion of the light emitting device layer through the openings. Thereafter, a conductive layer is formed on the first ohmic contact layer. Then, the substrate is removed so as to expose the second surface of the light emitting device layer. Next, a first electrode layer is formed on the second surface so as to cover a portion of the light emitting device layer, and a second electrode layer is formed on the conductive layer.

According to an embodiment of the invention, a method of forming the first ohmic contact layer includes an electroplating process, an evaporating process, a sputtering process, or a deposition process.

According to an embodiment of the invention, before forming the conductive layer on the first ohmic contact layer, the fabrication method further includes forming a second ohmic contact layer on the first ohmic contact layer, and a portion of the second ohmic contact layer is adapted to fill the openings and to connect with a portion of the first ohmic contact layer in the openings.

According to an embodiment of the invention, a method of forming the conductive layer on the first ohmic contact layer includes a bonding process or an electroplating process.

According to an embodiment of the invention, when the conductive layer is formed on the first ohmic contact layer by the electroplating process, the conductive layer is adapted to fill the openings and to connect with the first ohmic contact layer.

According to an embodiment of the invention, a method of removing the substrate so as to expose the second surface of the light emitting device layer includes a laser lift-off process. Another aspect of the invention provides an LED structure, including a light emitting device layer, an ohmic contact layer, a conductive layer, a first electrode layer, and a second electrode layer. The light emitting device layer has a first surface, a second surface, a plurality of protruded portions, and a plurality of recessed portions. The protruded portions and the recessed portions are disposed on the first surface. The ohmic contact layer covers first surface, and the ohmic contact layer fills the recessed portions and connects with a portion of the light emitting device layer. The conductive layer is disposed on and connected with the ohmic contact layer. The first electrode layer is disposed on the second surface and covers a portion of the light emitting device layer. The second electrode layer is disposed on the conductive layer, and the conductive layer is disposed between the ohmic contact layer and the second electrode layer.

According to an embodiment of the invention, the ohmic contact layer is conformal with the protruded portions and the recessed portions.

According to an embodiment of the invention, the conductive layer fills the recessed portions and connects with the ohmic contact layer.

According to an embodiment of the invention, the LED structure further includes a plurality of dielectric layers respectively disposed on the protruded portions, and each of the dielectric layers is located between the light emitting device layer and the conductive layer. According to an embodiment of the invention, a material of the dielectric layers comprises SiOₓ, SiNₓ, SiNₓO_{y}, SiₓC_{y}, HfO, AlOₓ, or photoresist materials, wherein x, y are larger than 0 and smaller than 4.

According to an embodiment of the invention, the ohmic contact layer is adapted to fill the openings, and the ohmic contact layer is a planar layer. According to an embodiment of the invention, a material of the ohmic contact layer comprises metallic materials, transparent conductive oxides, or semiconductor materials. According to an embodiment of the invention, the ohmic contact layer has a single layer structure or a multi-layer structure.

According to an embodiment of the invention, a pattern formed by the protruded portions and the recessed portions on the first surface includes a structure of a protruded or recessed symmetrical pattern, asymmetrical pattern, trapezoidal pattern, or conical pattern.

According to an embodiment of the invention, a material of the light emitting device layer comprises GaN, AlGaN, AlGaInN, AlInGaP, AlGaAs, InGaAs, or a combination thereof. According to an embodiment of the invention, the light emitting device layer includes a first type semiconductor layer, a light emitting layer, and a second type semiconductor layer. The light emitting layer is disposed between the first type semiconductor layer and the second type semiconductor layer.

Another aspect of the invention provides a method of fabricating an LED structure, the method including at least the following steps. First, a substrate is provided. Next, a light emitting device layer is formed on the substrate, in which the light emitting device layer has a first surface and a second surface opposite to the first surface, and the second surface is in contact with the substrate. Thereafter, a dielectric layer is formed on the first surface of the light emitting device layer. Then, the dielectric layer is patterned to form a patterned dielectric layer having a plurality of openings, in which the openings expose a portion of the light emitting device layer. Thereafter, by using the patterned dielectric layer as a mask, a portion of the light emitting device layer exposed by the openings is removed. Moreover, a plurality of recessed portions and a plurality of protruded portions corresponding to the recessed portions are formed on the first surface. Additionally, the patterned dielectric layer is disposed on the protruded portions. Then, an ohmic contact layer is formed on the first surface, in which the ohmic contact layer is adapted to fill the recessed portions and to connect with a portion of the light emitting device layer. Thereafter, a conductive layer is formed on the ohmic contact layer. Then, the substrate is removed so as to expose the second surface of the light emitting device layer. Next, a first electrode layer is formed on the second surface so as to cover a portion of the light emitting device layer, and a second electrode layer is formed on the conductive layer.

According to an embodiment of the invention, a method of forming the ohmic contact layer includes an electroplating process, an evaporating process, a sputtering process, or a deposition process.

According to an embodiment of the invention, a method of forming the conductive layer on the ohmic contact layer includes a bonding process or an electroplating process.

According to an embodiment of the invention, when the conductive layer is formed on the ohmic contact layer by the electroplating process, the conductive layer is adapted to fill the recessed portions and to connect with the ohmic contact layer.

According to an embodiment of the invention, when the ohmic contact layer is formed on the first surface, the fabrication method further includes adapting the ohmic contact layer to fill the recessed portions and to connect with the light emitting device layer.

According to an embodiment of the invention, before forming the ohmic contact layer on the first surface, the fabrication method further includes removing the patterned dielectric layer disposed on the protruded portions.

According to an embodiment of the invention, a method of removing the substrate so as to expose the second surface of the light emitting device layer includes a laser lift-off process.

In an LED structure according to an embodiment of the invention, by adopting the reflective structure formed by the patterned dielectric layer and the ohmic contact layer, when the light beams generated by the light emitting device layer are transmitted to the patterned dielectric layer, the light beams are reflected by the ohmic contact layer. Moreover, when the reflected light beams are emitted from the second surface, the light exiting angle thereof approaches an omni-directional light field distribution. Accordingly, the light exiting angle provided by the LED structure is substantially large.

Furthermore, when the ohmic contact layer comprises stacked layers of transparent conductive oxides and reflective metals, the overall electrical characteristic and light emitting efficiency of the LED structure are effectively enhanced. Additionally, by designing protruded and recessed portions on the surface of the light emitting device layer and configuring the ohmic contact layer to directly cover the protruded and recessed portions, an contact area of the ohmic contact layer and the light emitting device layer is increased. Accordingly, besides achieving a preferable optical performance, the LED structure may also have an enhanced electrical characteristic. Furthermore, the fabrication method provided by embodiments of the invention fabricates the LED structure having the foregoing advantages by only using a single substrate transfer process. Hence, the fabrication method has substantially simpler steps.

In order to make the aforementioned and other features and advantages of the invention more comprehensible, embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a partial cross-sectional view of an LED structure in accordance with a first embodiment of the invention.

FIG. 2A is a partial enlarged view of FIG. 1.

FIG. 2B is a partial enlarged view of another implementation of FIG. 1.

FIGS. 3A-3F are schematic cross-sectional views showing a process of fabricating an LED structure in accordance with the first embodiment of the invention.

FIG. 4 is a partial cross-sectional view of another implementation of an LED structure in accordance with the first embodiment of the invention.

FIG. 5 is a partial cross-sectional view of an LED structure in accordance with a second embodiment of the invention.

FIGS. 6A-6D are schematic cross-sectional views showing a process of fabricating an LED structure in accordance with the second embodiment of the invention.

FIG. 7 is a partial cross-sectional view of another implementation of an LED structure in accordance with the second embodiment of the invention.

FIG. 8 is a partial cross-sectional view of another implementation of an LED structure in accordance with the second embodiment of the invention.

### DESCRIPTION OF EMBODIMENTS

### First Embodiment

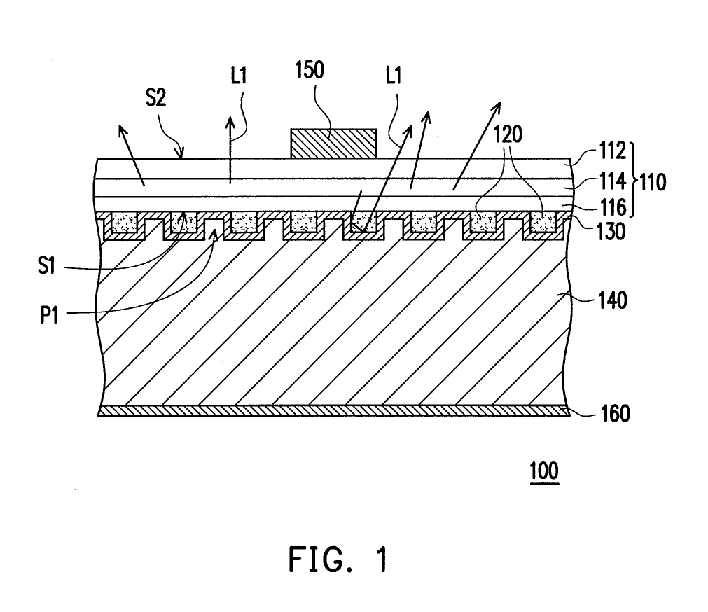

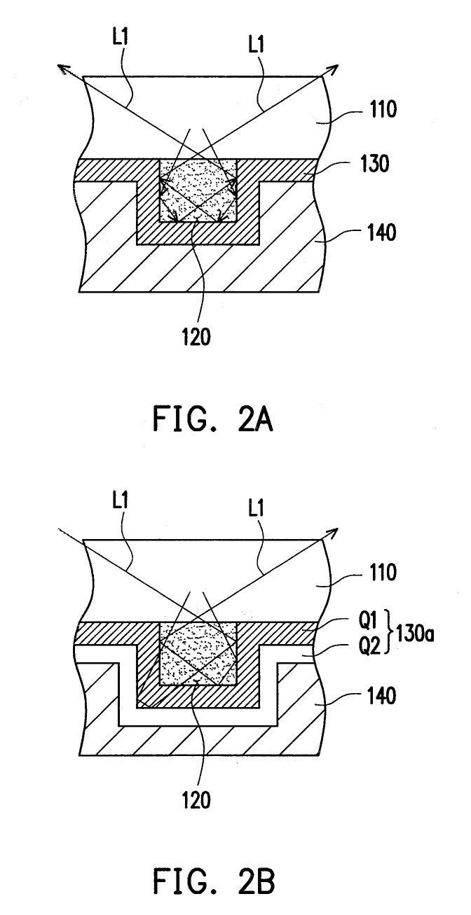

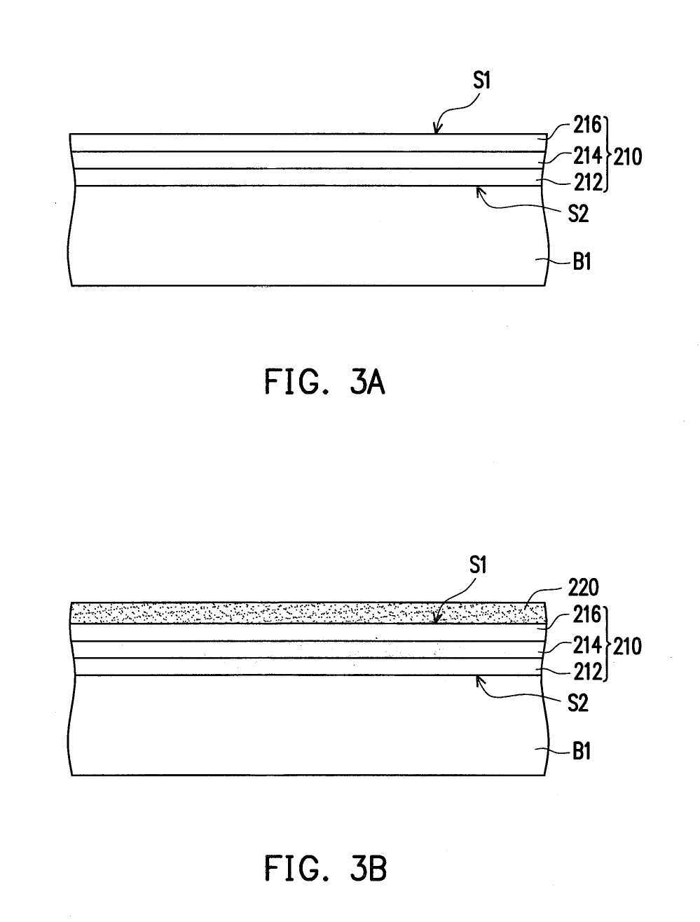

FIG. 1 is a partial cross-sectional view of a light emitting diode (LED) structure in accordance with a first embodiment of the invention. FIG. 2A is a partial enlarged view of FIG. 1. Referring to FIGS. 1 and 2A, an LED structure 100 according to the present embodiment includes a light emitting device layer 110, a patterned dielectric layer 120, a first ohmic contact layer 130, a conductive layer 140, a first electrode layer 150, and a second electrode layer 160. The light emitting device layer 110 has a first surface S1 and a second surface S2. In the present embodiment, the light emitting device layer 110 includes a first type semiconductor layer 112, a light emitting layer 114, and a second type semiconductor layer 116. The light emitting layer 114 is disposed between the first type semiconductor layer 112 and the second type semiconductor layer 116. More specifically, the first type semiconductor layer 112 is exemplarily a N-type semiconductor layer, the second type semiconductor layer 116 is exemplarily a P-type semiconductor layer, and the light emitting layer 114 may be a plurality of quantum well layers. On the other hand, the first type may also be P-type, whereas the second type may be N-type, and the types of semiconductor layers may be adjusted by a user accordingly.

In the present embodiment, as an illustrative example, the first type semiconductor layer 112 and the second type semiconductor layer 116 are exemplarily N-type and P-type semiconductor layers, respectively. Moreover, a material of the light emitting device layer 110 may comprise GaN, AlGaN, AlGaInN, AlInGaP, AlGaAs, InGaAs, or a combination thereof. The present embodiment exemplarily uses GaN as an illustrative example, and the invention is not limited thereto.

Continuing reference to FIGS. 1 and 2A, the patterned dielectric layer 120 is disposed on the light emitting device layer 110, and the patterned dielectric layer 120 exposes the light emitting device layer 110. In the present embodiment, a material of the patterned dielectric layer may comprise insulating materials such as SiOₓ, SiNₓ, SiNₓO_{y}, SiₓC_{y}, HfO, AlOₓ, or photoresist materials, wherein x, y are larger than 0 and smaller than 4. Although the present embodiment uses photoresist materials as an illustrative example, the invention is not limited thereto. Moreover, the patterned dielectric layer may be designed to have a plurality of different structures according to a user designed photomask pattern. For example, according to different designs of photomask patterns, a pattern formed on the patterned dielectric layer 120 may include a structure of a protruded or recessed symmetrical pattern, asymmetrical pattern, trapezoidal pattern, or conical pattern.

It is worth noting that the material of the patterned dielectric layer 120 according to the present embodiment may comprise of transparent materials.

Furthermore, as shown in FIGS. 1 and 2A, the first ohmic contact layer 130 is disposed on the patterned dielectric layer 120 and connected with the light emitting device layer 110 through the patterned dielectric layer 120. In the present embodiment, the first ohmic contact layer 130 is conformal with the patterned dielectric layer 120. Moreover, when the first ohmic contact layer 130 is exemplarily a single layer structure, a material thereof may comprise a metal having a high reflectivity, such as silver or aluminum. More specifically, since the material of the patterned dielectric layer 120 may comprise of transparent materials, therefore when the LED structure 100 is driven such that the light emitting device layer 110 is excited and emits a plurality of light beams L1, a portion of the light beams L1 transmitted to the patterned dielectric layer 120 is reflected by the first ohmic contact layer 130 covering the patterned dielectric layer 120. Moreover, since the patterned dielectric layer 120 adopts the structure of a protruded or recessed symmetrical pattern, asymmetrical pattern, trapezoidal pattern, or conical pattern, when the light beams L1 are reflected by the first ohmic contact layer 130 and emitted from the second surface S2, the emitted light field distribution may substantially approach an omni-directional light field distribution. Thereby, the light field distribution provided by the LED structure 100 may be uniform.

It should be noted that, in order for full diffraction or scattering of the light emitted by the light emitting device layer 110, a step difference or a depth of the protruded or recessed structure of the patterned dielectric layer 110 must be at least λ/4. Accordingly, when the step difference or the depth of the protruded or recessed structure is λ/4n (where n is a refractive index of the semiconductor layer), a diffraction effect is achieved. For full light diffraction or scattering, a distance between the protruded or recessed structure is less than 100 μm. In order to obtain a preferable diffraction effect, the distance between the protruded or recessed structure should be preferably less than 20 μm, so as to effectively reduce an occurrence of a total reflection phenomenon.

In another implementation, besides the first ohmic contact layer 130 having the aforesaid single layer structure, a first ohmic contact layer 130a as shown in FIG. 2B having a structure of a plurality of layers Q1 and Q2 may also be adopted. In the first ohmic contact layer 130a depicted in FIG. 2B, a material of the ohmic contact layer Q1 may comprise of transparent conductive oxides (e.g., indium tin oxide (ITO)) or metallic materials such as nickel. A material of the ohmic contact layer Q2 may comprise of the aforementioned metal having a high reflectivity, such as silver or aluminum. In more specifics, when the LED structure 100 adopts the first ohmic contact layer 130a depicted in FIG. 2B, for example, and the ohmic contact layer Q1 comprises transparent conductive oxides, not only the advantages mentioned while describing FIG. 2A are achieved, an overall electrical characteristic and light emitting efficiency of the LED structure 100 may be enhanced.

Additionally, as shown in FIGS. 1 and 2A, the conductive layer 140 is disposed on and connected with the first ohmic contact layers 130 and 130a. In the present embodiment, the conductive layer 140 may be a layer comprising metallic materials. A connection method of the conductive layer 140 and the first ohmic contact layer 130 may be an adhesion, bonding, or electroplating process, and the connection method may be determined according to a user need. In the present embodiment, the connection method of the conductive layer 140 and the first ohmic contact layer 130 is preferably an electroplating process.

It is worth mentioning that, in an unillustrated embodiment of the invention, when the first ohmic contact layer 130 is a planar layer, then the conductive layer 140 may be connected with the first ohmic contact layer 130 by using the adhesion process, although the electroplating process may also be adopted.

Continuing reference to FIGS. 1 and 2A, the first electrode layer 150 is disposed on the second surface S2 and covers a portion of the light emitting device layer 110. The second electrode layer 160 is disposed on the conductive layer 140, and the conductive layer 140 is disposed between the first ohmic contact layer 130 and the second conductive layer 160. In the present embodiment, the first electrode layer 150 is a N-type electrode of the first type semiconductor layer 112, whereas the second electrode layer 160 may be a P-type electrode of the second type semiconductor layer 116. More specifically, when a driving voltage is applied to the first electrode layer 150 and the second electrode layer 160, then the light emitting device layer 110 is excited and generates the light beams L1.

In view of the foregoing description, for the LED structure 100 according to the present embodiment, by adopting the structure formed by the patterned dielectric layer 120 and the first ohmic contact layers 130 and 130a covering the patterned dielectric layer 120, when the plurality of light beams L1 generated by the light emitting device layer 110 are transmitted to the patterned dielectric layer 120, the light beams L1 may be reflected by the first ohmic contact layers 130 and 130a. Moreover, since the surface of the first ohmic contact layers 130 and 130a in contact with the patterned dielectric layer 120 is an irregular surface, when the reflected light beams L1 are emitted from the second surface S2, a corresponding light exiting angle approaches an omni-directional light field distribution. Accordingly, the light exiting angle provided by the LED structure 100 is substantially large. In more specifics, when the LED structure 100 adopts the first ohmic contact layer 130a depicted in FIG. 2B, for example, and the ohmic contact layer Q1 comprises transparent conductive oxides and the ohmic contact layer Q2 comprises reflective metals, the overall electrical characteristic and light emitting efficiency of the LED structure 100 may be enhanced.

It should be understood that, when the first ohmic contact layer 130 comprises only transparent conductive oxides, then the light beams L1 may be reflected by the conductive layer 140.

Furthermore, a method of fabricating the above-described LED structure 100 is also provided by the present embodiment as described in the following.

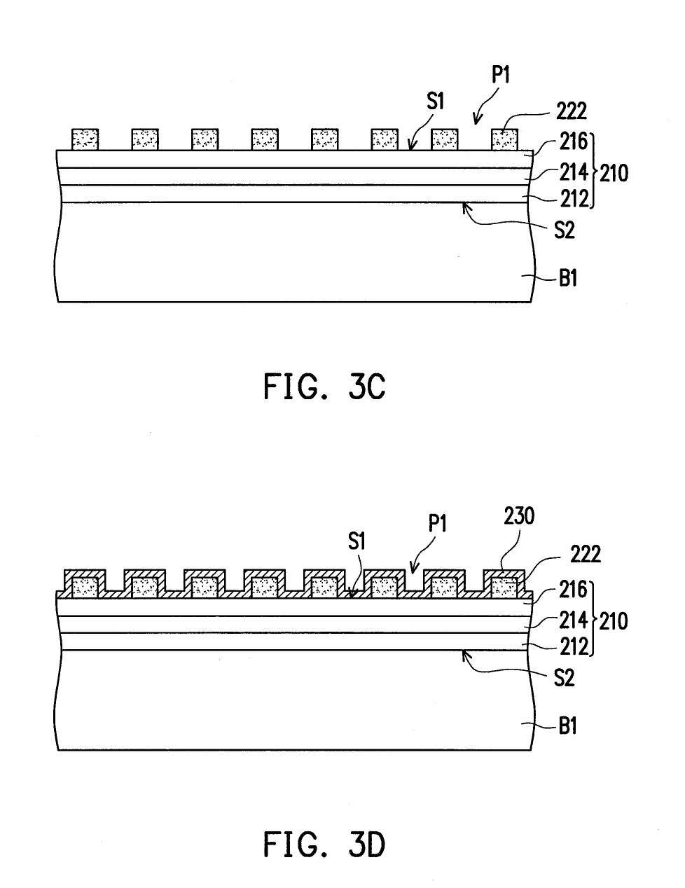

FIGS. 3A-3F are schematic cross-sectional views showing a process of fabricating an LED structure in accordance with the first embodiment of the invention. Referring to FIG. 3A, first a substrate B1 is provided. The substrate B1 is a growth substrate such as a single crystal silicon substrate, a silicon-on-insulating (SOI) substrate, or a sapphire (Al₂O₃) substrate. According to the present embodiment, the substrate B1 is exemplarily the sapphire substrate as an illustrative example, although the invention is not limited thereto. Thereafter, a light emitting device layer 210 is formed on the substrate B1. As shown in FIG. 3A, the light emitting device layer 210 has a first surface S1 and a second surface S2 opposite to the first surface S1, and the second surface S2 is in contact with the substrate B1. In the present embodiment, a material of the light emitting device layer 210 exemplarily comprises GaN, and the light emitting device layer 210 has a N-type semiconductor layer 212, a light emitting layer 214, and a P-type semiconductor layer 216, as shown in FIG. 3A.

Next, a dielectric layer 220 is formed on the first surface S1 of the light emitting device layer 210, as shown in FIG. 3B. In the present embodiment, a material of the dielectric layer 220 may comprise of the aforesaid materials of the patterned dielectric layer 120, although the present embodiment exemplarily uses photoresist materials as an illustrative example.

Thereafter, the dielectric layer 220 is patterned to form a patterned dielectric layer 222 having a plurality of openings P1. The openings P1 are configured such that the patterned dielectric layer 120 has a plurality of protruded or recessed structures, as shown in FIG. 3C. Moreover, the openings P1 expose a portion of the light emitting device layer 210. In the present embodiment, a method of patterning the dielectric layer 220 may be a conventional photolithography and etching process (PEP), for example.

Next, a first ohmic contact layer 230 is disposed on the patterned dielectric layer 222, in which the first ohmic contact layer 230 connects to a portion of the light emitting device layer 210 through the openings P1, as shown in FIG. 3D. In the present embodiment, a method of forming the first ohmic contact layer 230 may be an electroplating process, an evaporating process, a sputtering process, or a deposition process. Moreover, the first ohmic contact layer 230 is conformally formed on the patterned dielectric layer 222, and the first ohmic contact layer 230 may be designed to have a structure according to the first ohmic contact layers 130 and 130a depicted in FIGS. 2A and 2B.

Thereafter, a conductive layer 240 is formed on the first ohmic contact layer 230, as shown in FIG. 3E. In the present embodiment, a method of forming the conductive layer 240 on the first ohmic contact layer 230 may be a bonding process or an electroplating process, for example. Although the present embodiment uses the electroplating process as an illustrative example, the invention is not limited thereto. For example, when the first ohmic contact layer 230 is conformally formed on the patterned dielectric layer 220, then the electroplating process may be employed to form and connect the conductive layer 240 on the first ohmic contact layer 230.

Next, the substrate B1 is removed so as to expose the second surface S2 of the light emitting device layer 210, as shown in FIG. 3F. In the present embodiment, a method of removing the substrate B1 so as to expose the second surface S2 of the light emitting device layer 210 may be a laser lift-off process, for example.

Thereafter, a first electrode layer 150 is formed on the second surface S2 so as to cover a portion of the light emitting device layer 210. Moreover, a second electrode layer 160 is formed on the conductive layer 240. The LED structure 100 depicted in FIG. 1 is substantially formed at this point. In the present embodiment, a method of forming the first electrode layer 150 and the second electrode layer 160 may be an electroplating process, an evaporating process, a sputtering process, or a deposition process, for example.

According to the foregoing steps, besides being capable of fabricating the LED structure 100, the fabrication method provided by the present embodiment can fabricate the LED structure 100 depicted in FIG. 1 by employing only a single substrate transfer process. Therefore, the fabrication method contains substantially simpler steps.

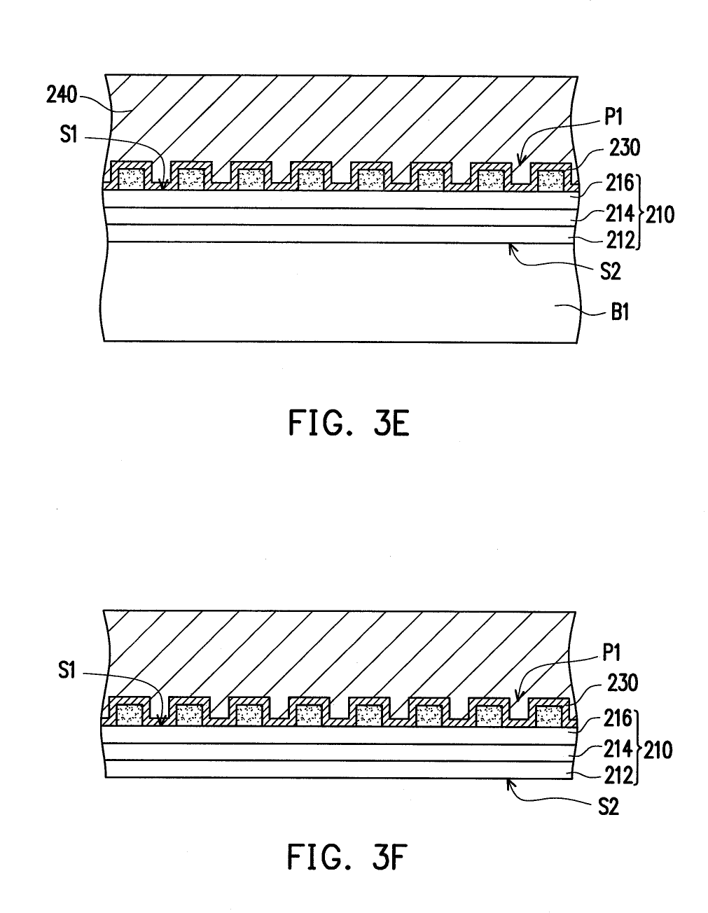

In another implementation, the LED structure 100 further includes a second ohmic contact layer 170 for forming, exemplarily, an LED structure 300 depicted in FIG. 4. The second ohmic contact layer 170 covers the first ohmic contact layer 130, and the second ohmic contact layer 170 is disposed between the first ohmic contact layer 130 and the conductive layer 140. In the LED structure 300, the second ohmic contact layer 170 is adapted to cover the first ohmic contact layer 130 and fill the openings P1 of the patterned dielectric layer 120. Moreover, the second ohmic contact layer 170 may be a planar layer, as shown in FIG. 4.

In the present embodiment of the invention, a material of the first ohmic contact layer 130 may comprise of transparent conductive oxides (e.g., ITO) or metallic materials such as nickel. A material of the second ohmic contact layer 170 may comprise of a metal having a high reflectivity, such as silver or aluminum.

Since the LED structure 300 is slightly different structurally from the LED structure 100, the fabrication method of the LED structure 300 also varies slightly from the fabrication method of the LED structure 100. A difference therebetween resides in that, before forming the conductive layer 140 on the first ohmic contact layer 130, the fabrication method of the LED structure 300 further includes disposing a second ohmic contact layer 170 on the first ohmic contact layer 130. Moreover, a portion of the second ohmic contact layer 170 is adapted to cover the first ohmic contact layer 130 and fill the patterned dielectric layer 220, as well as to connect to the first ohmic contact layer 130.

In the present embodiment, since the LED structures 300 and 100 differ only slightly in structure and in their fabrication methods, therefore the LED structure 300 and the fabrication method thereof similarly possess the aforementioned advantages of the LED 100 and the fabrication method of the LED 100.

### Second Embodiment

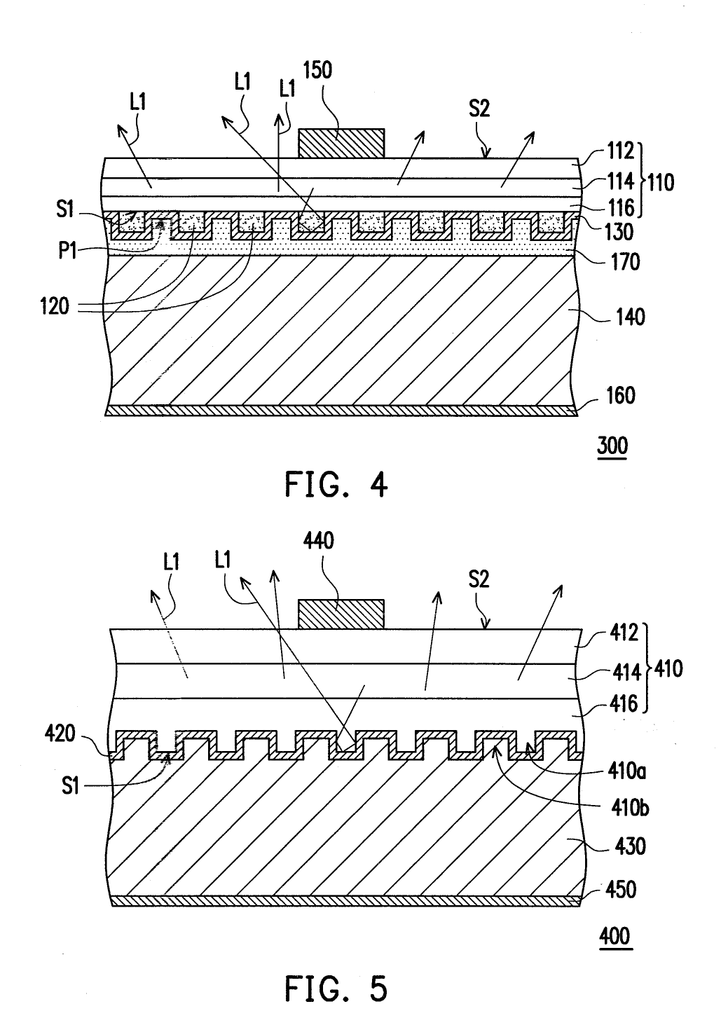

FIG. 5 is a partial cross-sectional view of an LED structure in accordance with a second embodiment of the invention. Referring to FIG. 5, an LED structure 400 according to the present embodiment includes a light emitting device layer 410, an ohmic contact layer 420, a conductive layer 430, a first electrode layer 440, and a second electrode layer 450. The light emitting device layer 410 has a first surface S1, a second surface S2, a plurality of continually disposed protruded portions 410a and a plurality of recessed portions 410b. The protruded portions 410a and the recessed portions 410b are disposed on the first surface S1. In the present embodiment, the protruded portions 410a and the recessed portions 410b disposed on the first surface S1 are patterned according to a photomask pattern design (e.g., an etching process). The pattern formed on the first surface S1 by the protruded portions 410a and the recessed portions 410b may include a structure of a protruded or recessed symmetrical pattern, asymmetrical pattern, trapezoidal pattern, or conical pattern. In order for full diffraction or scattering of the light emitted by the light emitting device layer 410, a step difference or a depth of the protruded portions 410a and the recessed portions 410b must be at least λ/4. Accordingly, when the step difference or the depth of the protruded portions 410a and the recessed portions 410b is λ/4n (where n is a refractive index of the light emitting device layer), a diffraction effect is achieved. For full light diffraction or scattering, a distance between the protruded portions 410a and the recessed portions 410b is preferably less than 100 μm. To achieve a preferable diffractive state, a distance of less than 20 μm effectively reduces an occurrence of a total reflection phenomenon. Since the light emitting device layer 410 has a plurality of continually disposed protruded portions 410a and a plurality of recessed portions 410b, therefore a heat-spread area is increased, thereby enhancing a heat dissipation capability of the heat generated by the light emitting device layer 410.

In the present embodiment, the light emitting device layer 410 includes a first type semiconductor layer 412, a light emitting layer 414, and a second type semiconductor layer 416. The light emitting layer 414 is disposed between the first semiconductor layer 412 and the second type semiconductor layer 416. More specifically, the first type semiconductor layer 412 is exemplarily a N-type semiconductor layer, the second type semiconductor layer 416 is exemplarily a P-type semiconductor layer, and the light emitting layer 414 may be a plurality of quantum well layers. Conversely, the first type may also be P-type, whereas the second type may be N-type, and the types of semiconductor layers may be adjusted by the user accordingly.

In the present embodiment, as an illustrative example, the first type semiconductor layer 412 and the second type semiconductor layer 416 are exemplarily N-type and P-type semiconductor layers, respectively. Moreover, a material of the light emitting device layer 410 may comprise GaN, AlGaN, AlGaInN, AlInGaP, AlGaAs, InGaAs, or a combination thereof. The present embodiment exemplarily uses GaN as an illustrative example, and the invention is not limited thereto.

Referring to FIG. 5, the ohmic contact layer 420 covers the first surface S1 and is connected with the light emitting device layer 410. In the present embodiment, the ohmic contact layer 420 is conformal with the protruded portions 410a and the recessed portions 410b. Moreover, when the ohmic contact layer 420 is exemplarily a single layer structure, a material thereof may comprise a metal having a high reflectivity, such as silver or aluminum. In more specifics, when the LED structure 400 is driven such that the light emitting device layer 410 is excited and emits a plurality of light beams L1, a portion of the light beams L1 transmitted to the ohmic contact layer 420 is reflected by the ohmic contact layer 420. Moreover, since the ohmic contact layer 420 is conformal with the protruded portions 410a and the recessed portions 410b, when the light beams L1 are reflected by the ohmic contact layer 420 and emitted from the second surface S2, the emitted light field distribution thereof may substantially approach an omni-directional light field distribution. Thereby, the light field distribution provided by the LED structure 400 may be uniform. In another unillustrated implementation, besides the ohmic contact layer 420 having the single layer structure, a design of a multi-layer structure previously described in the depiction of FIGS. 2A and 2B may be adopted, so further explanation is omitted hereafter.

It should be noted that, due to the light emitting device layer 410 having the protruded portions 410a and the recessed portions 410b, and because the ohmic contact layer 420 directly covers the protruded portions 410a and the recessed portions 410b, therefore in the present embodiment, a contact area of the ohmic contact layer 420 and the light emitting device layer 410 is increased. Accordingly, besides achieving a preferable optical performance, the LED structure 400 may also have an enhanced electrical characteristic.

Additionally, as shown in FIG. 5, the conductive layer 430 is disposed on and connected with the ohmic contact layer 420. In the present embodiment, the conductive layer 430 may be a layer comprising metallic materials. A connection method between the conductive layer 430 and the ohmic contact layer 420 may be an adhesion, bonding, or electroplating process, and the connection method may be determined according to a user need. In the present embodiment, the connection method of the conductive layer 430 and the ohmic layer 420 is preferably the electroplating process.

It is worth mentioning that, in an unillustrated embodiment of the invention, when the ohmic contact layer 420 is a planar layer, then the conductive layer 430 may be connected with the ohmic contact layer 420 by using the adhesion process, although the electroplating process may also be adopted.

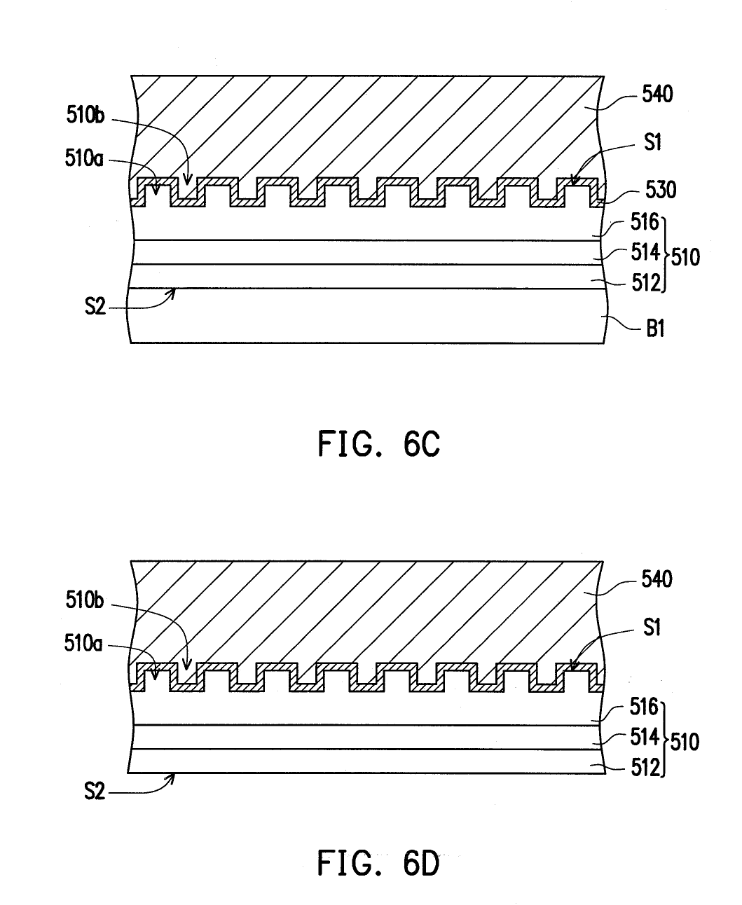

It should be noted that, in another embodiment, the LED structure 400 further includes a plurality of dielectric layers 460 respectively disposed on the protruded portions 410a of the light emitting device layer 410, so as to form an LED structure 600 depicted in FIG. 7. The dielectric layers 460 are respectively disposed between the ohmic contact layer 420 and the light emitting device layer 410. In the LED structure 600, a material of the dielectric layers 460 may comprise materials such as SiOₓ, SiNₓ, SiNₓO_{y}, SiₓC_{y}, HfO, AlOₓ, or photoresist materials, wherein x, y are larger than 0 and smaller than 4. Although the present embodiment uses photoresist materials as an illustrative example, the invention is not limited thereto, since insulating materials may also be adopted. Moreover, in the present embodiment, the ohmic contact layer 420 may comprise a metal having a high reflectivity, such as a material like silver or aluminum. It should be noted that, the step difference or the depth of the protruded portions 410a and the recessed portions 410b of the light emitting device layer 410 must be at least λ/4. When the step difference or the depth of the protruded portions 410a and the recessed portions 410b is λ/4n (where n is a refractive index of the semiconductor layer), a diffraction effect is achieved. For full light diffraction or scattering, the distance between the protruded portions 410a and the recessed portions 410b is preferably less than 100 μm. To achieve a preferable diffractive state, a distance of less than 20 μm effectively reduces the occurrence of the total reflection phenomenon.

Since the LED structure 600 is slightly different structurally from the LED structure 300, the fabrication method of the LED structure 600 also varies slightly from the fabrication method of the LED structure 300. A difference therebetween resides in that, for the LED structure 600 in the step depicted in FIG. 3B, during patterning the dielectric layers 460 and the P-type semiconductor layer 416 are concurrently patterned, so as to form a pattern on the first surface S1 with the protruded portions 410a and the recessed portions 410b, such as a structure of a protruded or recessed symmetrical pattern, asymmetrical pattern, trapezoidal pattern, or conical pattern.

In the present embodiment, since the LED structures 600 and 300 differ only slightly in structure and in their fabrication methods, therefore the LED structure 600 and the fabrication method thereof similarly possess the aforementioned advantages of the LED 300 and the fabrication method of the LED 300. Moreover, due to a high resistance property of the P-type semiconductor layer, therefore in the LED structure 600, after patterning the P-type semiconductor layer 416 so that the ohmic contact layer 420 closely approaches the light emitting layer 414, an effect that a high resistance value has on the LED structure 600 is reduced.

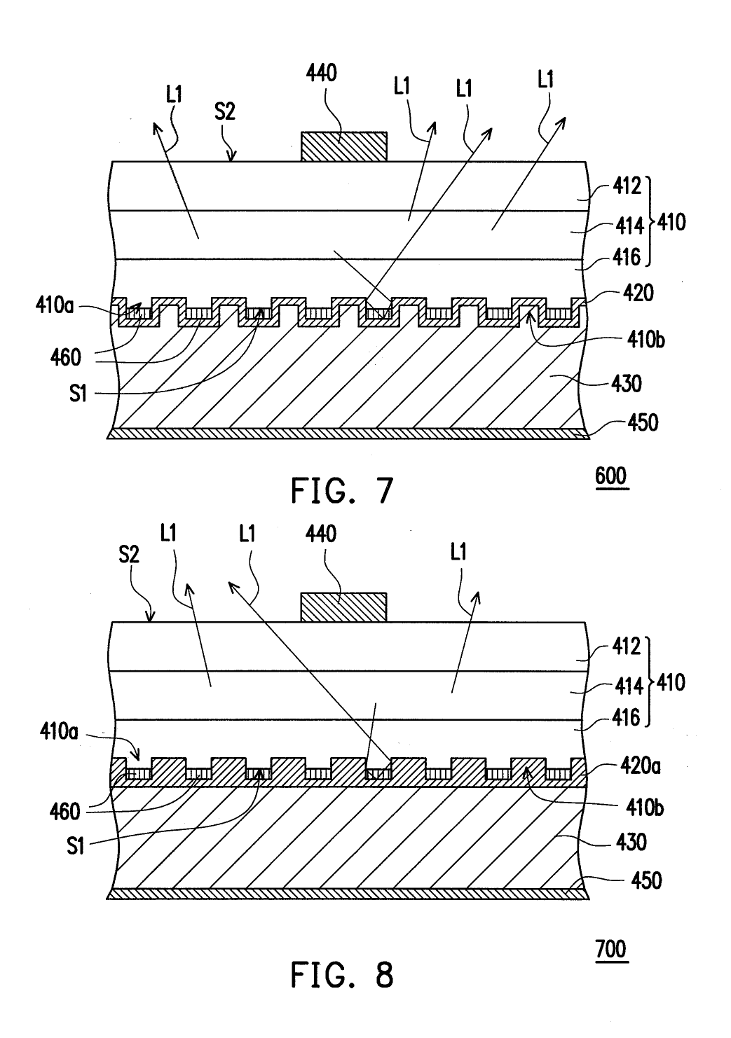

In another implementation, an ohmic contact layer 420a of an LED structure 700 may be implemented as filling the recessed portions 410a, as shown in FIG. 8. In this implementation, the ohmic contact layer 420a may be viewed as a planar layer. Hence, a formation method of the conductive layer 430 on the ohmic contact layer 420a is preferably an adhesion process, although an electroplating process may also be appropriate.

Continuing reference to FIG. 5, the first electrode layer 440 is disposed on the second surface S2 and covers a portion of the light emitting device layer 410. The second electrode layer 450 is disposed on the conductive layer 430, and the conductive layer 430 is disposed between the ohmic contact layer 420 and the second electrode layer 450. In the present embodiment, the first electrode layer 440 is a N-type electrode of the first type semiconductor layer 412, whereas the second electrode layer 450 may be a P-type electrode of the second type semiconductor layer 416. More specifically, when a driving voltage is applied to the first electrode layer 440 and the second electrode layer 450, then the light emitting device layer 410 is excited and generates the light beams L1.

In view of the foregoing description, the LED structure 400 according to the present embodiment may employ the protruded portions 410a and the recessed portions 410b of the ohmic contact layer 420 covering the light emitting device layer 410, such that when the plurality of light beams L1 generated by the light emitting device layer 410 are transmitted to the ohmic contact layer 420, the light beams L1 are reflected by the ohmic contact layer 420. Moreover, since the surface of the ohmic contact layer 420 in contact with the light emitting device layer 410 is an irregular surface S1, when the reflected light beams L1 are emitted from the second surface S2, a corresponding light exiting angle approaches an omni-directional light field distribution. Accordingly, the light exiting angle provided by the LED structure 400 is substantially large. Furthermore, when the double layer structure design depicted in FIG. 2B is adopted for the ohmic contact layer 420 of the LED structure 400, an overall electrical characteristic and light emitting efficiency of the LED structure 400 are effectively enhanced.

It should be understood that, when the ohmic contact layer 420 comprises only transparent conductive oxides, then the light beams L1 may be reflected by the conductive layer 430.

Additionally, the present embodiment provides a method of fabricating the LED structure 400, in which the fabrication method of the LED structure 400 is the same as the fabrication method of the LED structure 100 in the steps depicted in FIGS. 3A-3C. The fabrication method of the LED structure 400 after the step of FIG. 3C is different from the fabrication method of the LED 100, and an explanation is provided hereafter.

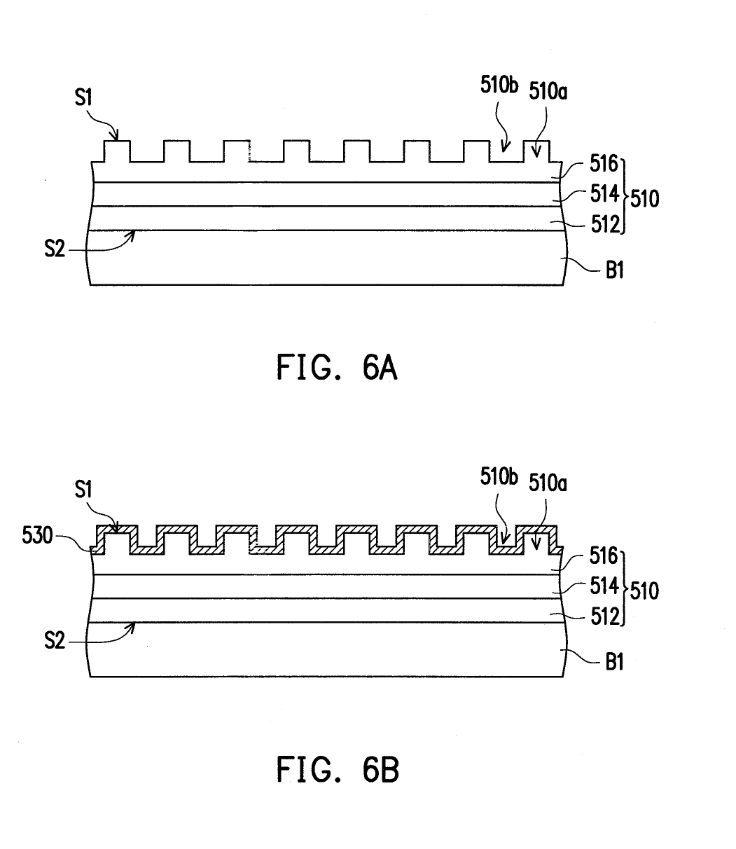

In the method of fabricating the LED structure 400, the previously described steps depicted in FIGS. 3A-3C are first completed. Thereafter, by using the patterned dielectric layer as a mask, a portion of the light emitting device layer 510 exposed by the openings P1 is removed. Moreover, a plurality of protruded portions 510a and a plurality of recessed portions 510b corresponding to the protruded portions 510a are formed on the first surface S1. The patterned dielectric layer is disposed between the protruded portions 510a. Next, as shown in FIG. 6A, the patterned dielectric layer is removed so as to expose the protruded portions 510a of the light emitting device layer 510. In the present embodiment, a method of removing the portion of the light emitting device layer 510 to form the protruded portions 510a and the recessed portions 510b may be a dry etching process or a wet etching process. Furthermore, a method of removing the patterned dielectric layer may be a dry etching process, a wet etching process, or by using a photoresist-striping liquid, for example. Since the present embodiment uses the patterned dielectric layer as photoresist, therefore the removal method of the patterned dielectric layer may be employing an organic liquid for photoresist striping.

Thereafter, an ohmic contact layer 530 is disposed on the first surface S1 and connected with the light emitting device layer 510, as shown in FIG. 6B. In the present embodiment, a method of forming the ohmic contact layer 530 may be an electroplating process, an evaporating process, a sputtering process, or a deposition process. Moreover, the ohmic contact layer 530 is conformal with the protruded portions 510a and the recessed portions 510b, and the ohmic contact layer 530 may be designed to have a single layer or multi-layer structure as depicted in FIGS. 2A and 2B, for example.

Next, a conductive layer 540 is formed on the ohmic contact layer 530, as shown in FIG. 6C. In the present embodiment, a method of forming the conductive layer 540 on the ohmic contact layer 530 may be a bonding process or an electroplating process. Although the present embodiment uses the electroplating process as an illustrative example, such that the conductive layer 540 is adapted to fill the recessed portions 510b and to connect to the ohmic contact layer 530, the invention is not limited thereto. For example, when the ohmic contact layer 530 forms a planar layer by filling the recessed portions 510b and covering the protruded portions 510a, then the conductive layer 540 may be formed on the ohmic contact layer 530 by the bonding process.

Thereafter, the substrate B1 is removed so as to expose the second surface S2 of the light emitting device layer 510, as shown in FIG. 6D. In the present embodiment, a method of removing the substrate B1 so as to expose the second surface S2 of the light emitting device layer 510 may be a laser lift-off process, for example.

Next, a first electrode layer 440 is formed on the second surface S2 so as to cover a portion of the light emitting device layer 510. Moreover, a second electrode layer 450 is formed on the conductive layer 540. The LED structure 400 depicted in FIG. 5 is substantially formed at this point. In the present embodiment, a method of forming the first electrode layer 440 and the second electrode layer 450 may be the electroplating process, the evaporating process, the sputtering process, or the deposition process.

According to the foregoing steps, besides being capable of fabricating the LED structure 400, the fabrication method provided by the present embodiment can fabricate the LED structure 400 depicted in FIG. 5 by employing only a single substrate transfer process. Therefore, the fabrication method contains substantially simpler steps.

In light of the above, the LED structure and the fabricating method thereof according to embodiments of the invention have at least the following advantages. First, by adopting the reflective structure formed by the patterned dielectric layer and the first ohmic contact layer, when the light beams generated by the light emitting device layer are transmitted to the patterned dielectric layer, the light beams are reflected by the first ohmic contact layer. Moreover, when the reflected light beams are emitted from the second surface, the light exiting angle thereof approaches an omni-directional light field distribution. Accordingly, the light exiting angle provided by the LED structure is substantially large. Furthermore, when the first ohmic contact layer comprises stacked layers of transparent conductive oxides and reflective metals, the overall electrical characteristic and light emitting efficiency of the LED structure are effectively enhanced. Additionally, by designing protruded and recessed portions on the surface of the light emitting device layer and configuring the ohmic contact layer to directly cover the protruded and recessed portions, the contact area of the ohmic contact layer and the light emitting device layer is increased. Accordingly, besides achieving a preferable optical performance, the LED structure may also have an enhanced electrical characteristic.

Furthermore, the fabrication method provided by embodiments of the invention fabricates the LED structure having the foregoing advantages by only using a single substrate transfer process. Hence, the fabrication method has substantially simpler steps.

Though the invention has been disclosed above by the embodiments, they are not intended to limit the invention. Anybody skilled in the art can make some modifications and variations without departing from the spirit and scope of the invention. Therefore, the protecting range of the invention falls in the appended claims.

What is claimed is:

1. A light emitting diode (LED) structure, comprising:
a light emitting device layer having a first surface and a second surface opposite to the first surface;
a patterned dielectric layer disposed on the first surface;
a first ohmic contact layer disposed on the patterned dielectric layer, and the first ohmic contact layer is connected with the light emitting device layer through the patterned conductive layer;
a conductive layer disposed on and connected with the first ohmic contact layer;
a first electrode disposed on the second surface; and
a second electrode disposed on a bottom surface of the conductive layer.

2. The LED structure as claimed in claim 1, wherein the first ohmic contact layer is conformal with the patterned dielectric layer.

3. The LED structure as claimed in claim 2, wherein the conductive layer is connected with the first ohmic contact layer through the patterned dielectric layer.

4. The LED structure as claimed in claim 2, further comprising a second ohmic contact layer formed on the first ohmic contact layer and disposed between the first ohmic contact layer and the conductive layer.

5. The LED structure as claimed in claim 4, wherein the second ohmic contact layer is a planar layer.

6. The LED structure as claimed in claim 1, wherein the light emitting device layer comprises a first type semiconductor layer, a light emitting layer, and a second type semiconductor layer, and the light emitting layer is disposed between the first type semiconductor layer and the second type semiconductor layer.

7. The LED structure as claimed in claim 1, wherein a pattern formed on the patterned dielectric layer comprises a structure of a protruded or recessed symmetrical pattern, asymmetrical pattern, trapezoidal pattern, or conical pattern.

8. A method of fabricating an LED structure, comprising:
providing a substrate;
forming a light emitting device layer on the substrate, wherein the light emitting device layer has a first surface and a second surface opposite to the first surface;
forming a dielectric layer on the first surface of the light emitting device layer;
patterning the dielectric layer to form a patterned dielectric layer having a plurality of openings, wherein the openings expose the light emitting device layer;
forming a first ohmic contact layer on the patterned dielectric layer, wherein the first ohmic contact layer is connected with the light emitting device layer through the openings;
forming a conductive layer on the first ohmic contact layer; and
removing the substrate so as to expose the second surface of the light emitting device layer.

9. The method of fabricating the LED structure as claimed in claim 8, wherein before forming the conductive layer on the first ohmic contact layer, the method further comprises forming a second ohmic contact layer on the first ohmic contact layer.

10. The method of fabricating the LED structure as claimed in claim 9, wherein a portion of the second ohmic contact layer is adapted to fill the openings and to connect with the first ohmic contact layer.

11. The method of fabricating the LED structure as claimed in claim 8, wherein when the conductive layer is formed on the first ohmic contact layer by an electroplating process, the conductive layer is adapted to fill the openings and to connect with the first ohmic contact layer. The method of fabricating the LED structure as claimed in claim 8, further comprising forming a first electrode on the second surface and forming a second electrode on a bottom surface of the conductive layer.

13. An LED structure, comprising:
a light emitting device layer having a first surface and a second surface opposite to the first surface, the first surface having a plurality of protruded portions and a plurality of recessed portions;
an ohmic contact layer covering the first surface and connected with the light emitting device layer;
a conductive layer disposed on and connected with the ohmic contact layer;
a first electrode disposed on the second surface; and
a second electrode disposed on a bottom surface of a conductive layer.

14. The LED structure as claimed in claim 13, wherein the ohmic contact layer is conformal with the protruded portions and the recessed portions.

15. The LED structure as claimed in claim 13, further comprising a plurality of dielectric layers respectively disposed on the protruded portions, and each of the dielectric layers is located between the light emitting device layer and the conductive layer.

16. The LED structure as claimed in claim 13, wherein the ohmic contact layer is adapted to fill the openings, and the ohmic contact layer is a planar layer.

17. The LED structure as claimed in claim 13, wherein the light emitting device layer comprises a first type semiconductor layer, a light emitting layer, and a second type semiconductor layer, and the light emitting layer is disposed between the first type semiconductor layer and the second type semiconductor layer.

18. The LED structure as claimed in claim 13, wherein a pattern formed by the protruded portions and the recessed portions on the first surface comprises a structure of a protruded or recessed symmetrical pattern, asymmetrical pattern, trapezoidal pattern, or conical pattern.

19. A method of fabricating an LED structure, comprising:
providing a substrate;
forming a light emitting device layer on the substrate, wherein the light emitting device layer has a first surface and a second surface opposite to the first surface, and the second surface is in contact with the substrate;
forming a dielectric layer on the first surface of the light emitting device layer;
patterning the dielectric layer to form a patterned dielectric layer having a plurality of openings, wherein the openings expose the light emitting device layer;
removing a portion of the light emitting device layer exposed by the openings by using the patterned dielectric layer as a mask, and forming a plurality of recessed portions and a plurality of protruded portions corresponding to the recessed portions on the first surface, wherein the patterned dielectric layer is disposed on the protruded portions;
forming an ohmic contact layer on the first surface, wherein the ohmic contact layer is adapted to fill the recessed portions and to connect with the light emitting device layer;
forming a conductive layer on the ohmic contact layer;
removing the substrate so as to expose the second surface of the light emitting device layer;
forming a first electrode layer on the second surface so as to cover a portion of the light emitting device layer; and
forming a second electrode layer on the conductive layer.

20. The method of fabricating the LED structure as claimed in claim 19, wherein when the conductive layer is formed on the ohmic contact layer by an electroplating process, the conductive layer is adapted to fill the recessed portions and to connect with the ohmic contact layer.

21. The method of fabricating the LED structure as claimed in claim 19, wherein when the ohmic contact layer is formed on the first surface, the method further comprises adapting the ohmic contact layer to fill the recessed portions and to connect with the light emitting device layer.

22. The method of fabricating the LED structure as claimed in claim 19, wherein before forming the ohmic contact layer on the first surface, the method further comprises removing the patterned dielectric layer disposed on the protruded portions.
